(19) United States
(12) Patent Application Publication
(10) Pub. No.: US 2013/0109118 A1
(43) Pub. Date: May 2, 2013

(54) METHOD OF MANUFACTURING ORGANIC ELECTROLUMINESCENCE DISPLAY DEVICE

(71) Applicant: CANON KABUSHIKI KAISHA, Tokyo (JP)

(72) Inventors: Atsushi Shiozaki, Mobara-shi (JP); Nobuhiko Sato, Mobara-shi (JP)

(73) Assignee: CANON KABUSHIKI KAISHA, Tokyo (JP)

(21) Appl. No.: 13/658,220

(22) Filed: Oct. 23, 2012

(30) Foreign Application Priority Data
Oct. 31, 2011 (JP) 2011-238344

(51) Int. Cl. H01L 51/56

(52) U.S. Cl. 438/34; 257/E51.018

(57) ABSTRACT

Provided is a method of manufacturing an organic electroluminescence display device including: forming, on a first pixel electrode and a second pixel electrode which are formed on a substrate, a charge injection transport layer which is formed of a charge injection transport material using a forming method capable of covering up a portion to be concealed; forming a first organic compound layer on the charge injection transport layer; processing the first organic compound layer to remove the first organic compound layer provided at least on the second pixel electrode; removing at least a part of the charge injection transport layer provided on the second pixel electrode; forming a second organic compound layer on the second pixel electrode; and forming a counter electrode which is common to a first pixel and a second pixel.

### BACKGROUND OF THE INVENTION

1. Field of the Invention

The present invention relates to a method of manufacturing an organic electroluminescence (EL) display device.

2. Description of the Related Art

In recent years, as a flat panel display, an organic EL display device which is a self emission type device is attracting attention.

As an organic EL display device which may display a color image, an organic EL display device is known in which multiple kinds of organic EL elements which emit light of different colors are arranged in matrix. The color of light emitted from an organic EL element is determined depending on a material contained in and the thickness of an organic compound layer forming the organic EL element. There are known several methods of manufacturing an organic EL display device in which multiple kinds of organic EL elements that emit light of different colors are arranged in matrix. Specifically, there are known a method in which an organic emission material is selectively vapor deposited in a predetermined region via a shadow mask, a method in which an organic emission material is applied to a predetermined region using an ink jet method or screen printing, a method in which laser light is applied to a donor substrate provided with an organic emission material to transfer the organic emission material to a substrate, and the like.

However, as display devices becomes finer in recent years, it becomes difficult to use the above-mentioned methods to form an organic compound layer in a desired location or region with high accuracy.

As measures to solve this problem, several proposals have been made to the present. Japanese Patent Application Laid-Open No. 2002-170673 proposes a method in which an organic compound layer formed on a substrate is patterned in a desired shape using photolithography to form on the substrate multiple organic compound layers which emit light of different colors.

On the other hand, when an organic compound layer is formed using only ordinary vacuum deposition, the organic compound layer is thinly formed (ordinarily, at a thickness of 1 μm or less). However, when there is a foreign matter, a small piece of an electrode material, a level difference in the pattern, or the like on a first electrode (lower electrode), depending on the size of the foreign matter or the like and the thickness of the organic compound layer, it is difficult to satisfactorily cover the foreign matter or the like with the organic compound layer. Further, when an organic compound layer develops therein an opening or a discontinuous portion due to the foreign matter or the like, electric leakage or a short circuit may occur between the first electrode below the organic compound layer (on the substrate side) and a counter electrode above the organic compound layer (on a side opposite to the substrate). This may cause an inconvenience that an electric field generated between the pair of electrodes is not satisfactorily applied to the organic emission layer to weaken or prevent the light emission. Accordingly, Japanese Patent Application Laid-Open No. 2011-054668 proposes a method of preventing electric leakage and a short circuit by forming, by an applying method, a layer which is a part of the organic compound layer and which is in contact with the first electrode (lower electrode).

However, when the methods proposed in Japanese Patent Application Laid-Open Nos. 2002-170673 and 2011-054668 are adopted in forming multiple kinds of organic compound layers which emit light of different colors in specified regions, respectively, the following problems arise.

When an organic compound layer is formed by the applying method as in Japanese Patent Application Laid-Open No. 2011-054668, after a constituent material of the organic compound layer is mixed with a specific solvent to prepare a solution, the prepared solution is applied on the substrate. A constituent material of an organic compound layer generally has properties of being sensitive to heat and moisture and being very soluble in an organic solvent solution. Therefore, when multiple kinds of organic compound layers which emit light of different colors are formed color-by-color, in particular, when the organic compound layers of the second and subsequent colors are formed, the solvent contained in the application liquid may also dissolve an organic compound layer formed prior to an organic compound layer as the target of film formation by application of the liquid. Therefore, such an organic compound layer formed prior to the organic compound layer as the target of film formation by application of the liquid may be damaged.

It follows that a constituent material of an organic compound layer of the first color is required to be insoluble in a solvent used when the organic compound layers of the second and subsequent colors are formed by application. However, in selecting constituent materials of the organic compound layers of the first color and the second color and of a release layer, and solvents to be mixed with the constituent materials, respectively, the interrelationship between specific constituent materials and specific solvents with regard to insolubility is required to be considered and materials and solvents which satisfy the relationship are required to be selected. Therefore, limitations imposed on the constituent materials and the solvents to be used are severe, which narrows the range of selection of the materials. Further, in manufacturing a display device which emits three colors used in ordinary color display, limitations on the organic compound layer of the third color are additionally imposed, which further narrows the range of selection of the materials.

Further, when a constituent material of an organic compound layer is a low molecular material, a solvent to be used is, in most cases, limited to a nonpolar solvent such as toluene or chloroform. Therefore, the range of selection of a solvent which does not dissolve an organic compound layer formed prior to the organic compound layer as the target of the above-mentioned film formation by application becomes narrower.

From the above, it can be said that, in manufacturing an organic EL display device which emits light of multiple kinds of colors using the method disclosed in Japanese Patent Application Laid-Open No. 2002-170673 on the precondition that the problem disclosed in Japanese Patent Application Laid-Open No. 2011-054668 (electric leakage and a short circuit between a pixel electrode and a counter electrode) is solved, there are a lot of problems to be solved.

### SUMMARY OF THE INVENTION

The present invention has been made to solve the above-mentioned problems, and an object of the present invention is to provide a method of manufacturing an organic EL display device which prevents occurrence of electric leakage and a short circuit between electrodes and still may use a broad range of materials as a constituent material of an organic EL element.

According to the present invention, there is provided a method of manufacturing an organic EL display device, including: forming, on a first pixel electrode and a second pixel electrode which are formed on a substrate, a charge injection transport layer which is formed of a charge injection transport material using a forming method capable of covering up the portion to be concealed; forming a first organic emission layer on the charge injection transport layer; processing the first organic emission layer to remove the first organic emission layer provided at least on the second pixel electrode; removing at least a part of the charge injection transport layer provided on the second pixel electrode; forming a second organic emission layer on the second pixel electrode; and forming a counter electrode which is common to a first pixel and a second pixel.

According to the present invention, it is possible to provide the method of manufacturing an organic EL display device which prevents occurrence of electric leakage and a short circuit between electrodes and still may use a broad range of materials as a constituent material of an organic EL element.

Further features of the present invention will become apparent from the following description of exemplary embodiments with reference to the attached drawings.

### BRIEF DESCRIPTION OF THE DRAWINGS

FIGS. 1A and 1B are perspective views illustrating specific examples of an organic EL display device manufactured by a manufacturing method according to the present invention.

FIGS. 2A, 2B, 2C, 2D, 2E, 2F, 2G, 2H, 2I, 2J, 2K, and 2L are schematic sectional views illustrating a method of manufacturing an organic EL display device according to a first embodiment of the present invention.

FIGS. 3A, 3B, 3C, 3D, 3E, 3F, 3G, 3H, 3I, 3J, 3K, 3L, 3M, 3N, and 3O are schematic sectional views illustrating a method of manufacturing an organic EL display device according to a second embodiment of the present invention.

### DESCRIPTION OF THE EMBODIMENTS

Preferred embodiments of the present invention will now be described in detail in accordance with the accompanying drawings.

A method of manufacturing an organic EL display device according to the present invention is a method of manufacturing an organic EL display device including at least two kinds of pixels, that is, a first pixel and a second pixel. Specifically, the method includes at least the following steps (i) to (vi). In this case, an organic EL element including an organic compound layer is located in each pixel, and, when the kind of the pixel is different, the organic compound layer in the pixel is different accordingly.

(i) Forming, on a first pixel electrode and a second pixel electrode which are formed on a substrate, a charge injection transport layer which is formed of a charge injection transport material using a forming method capable of covering up the portion to be concealed; (ii) forming a first organic compound layer on the charge injection transport layer; (iii) processing the first organic compound layer to remove the first organic compound layer provided at least on the second pixel electrode; (iv) removing at least a part of the charge injection transport layer provided on the second pixel electrode; (v) forming a second organic compound layer on the second pixel electrode; and (vi) forming a counter electrode which is common to the first pixel and the second pixel.

According to the manufacturing method of the present invention, by, in particular, carrying out the above-mentioned step (i), even if there is a foreign matter or a level difference on the pixel electrode, the charge injection transport material covers up the foreign matter or the level difference, and the charge injection transport material may go into a portion in the shadow. Therefore, in the step (iii), when a part of the first organic compound layer is removed, it is possible to leave the charge injection transport material in the portion in the shadow such as a foreign matter, a grain of an electrode material, or a level difference in the pattern, which may develop on the second pixel electrode. Therefore, when the second organic compound layer is formed by vacuum deposition or the like in a subsequent step, an opening or a discontinuous portion does not develop in the second organic compound layer. Therefore, occurrence of electric leakage and a short circuit between a pixel electrode and a counter electrode may be prevented not only in the first organic compound layer but also in the second organic compound layer.

Note that, the present invention is not only applied to an organic EL display device having two kinds of pixels, but also applicable to an organic EL display device having three kinds of pixels. According to the present invention, when an organic EL display device having three kinds of pixels (first pixel, second pixel, and third pixel) is manufactured, at least the following steps (i′) to (viii′) are included.

(i′) Forming, on a first pixel electrode, a second pixel electrode, and a third pixel electrode which are formed on a substrate, a charge injection transport layer which is formed of a charge injection transport material using a forming method capable of covering up the portion to be concealed; (ii′) forming a first organic compound layer on the charge injection transport layer; (iii′) processing the first organic compound layer to remove the first organic compound layer provided at least on the second pixel electrode and on the third pixel electrode; (iv′) forming a second organic compound layer by vacuum deposition in a region in which the second pixel electrode is provided; (v′) processing the second organic compound layer to remove the second organic compound layer provided on the first pixel electrode and on the third pixel electrode; (vi′) forming a third organic compound layer by vacuum deposition at least on the third pixel electrode; (vii′) processing the third organic compound layer to remove the third organic compound layer provided on the first pixel electrode and on the second pixel electrode; and (viii′) forming a counter electrode which is common to the first pixel, the second pixel, and the third electrode.

In this case, by, similarly to the case of the organic EL display device having two kinds of pixels, carrying out the above-mentioned step (i′), even if there is a foreign matter or a level difference on the pixel electrode, the charge injection transport material covers up the foreign matter or the level difference, and the charge injection transport material may go into a portion in the shadow. Therefore, in the step (iii′), when a part of the first organic compound layer is removed, it is possible to leave (fill) the charge injection transport material in the portion in the shadow of unevenness caused by a foreign matter or a crystal grain of an electrode material, or a level difference in the pattern, which may develop on the second pixel electrode and the third pixel electrode. Therefore, when the second organic compound layer and the third organic compound layer are formed by vacuum deposition or the like in a subsequent step, an opening or a discontinuous portion does not develop in these layers. Therefore, occurrence of electric leakage and a short circuit between a pixel electrode and a counter electrode may be prevented not only in the first organic compound layer but also in the second organic compound layer and the third organic compound layer. In this case, as the charge injection transport material according to the present invention, a material having the property of transporting charge injected from an electrode to an emission layer almost without recombination and having electrons at an energy level close to the energy level of electrons in an electrode material is preferred.

Further, the manufacturing method according to the present invention enables usage of vacuum deposition when the second organic compound layer and the third organic compound layer are formed, and thus, there are cases in which a solvent is not required to be used when the second organic compound layer and the third organic compound layer are formed. Specifically, even if the kinds of the pixels (kinds of organic compound layers to be formed) increase, it is not necessary to additionally impose limitations on the selection of the materials along with this increase, and thus, the range of selection of the materials is broad.

Embodiments of the present invention are described in the following with reference to the attached drawings as appropriate. Note that, technologies well-known or publicly-known to those skilled in the art are applied to portions which are not specifically illustrated or described herein. Further, embodiments described in the following are only exemplary embodiments of the present invention and the present invention is not limited thereto.

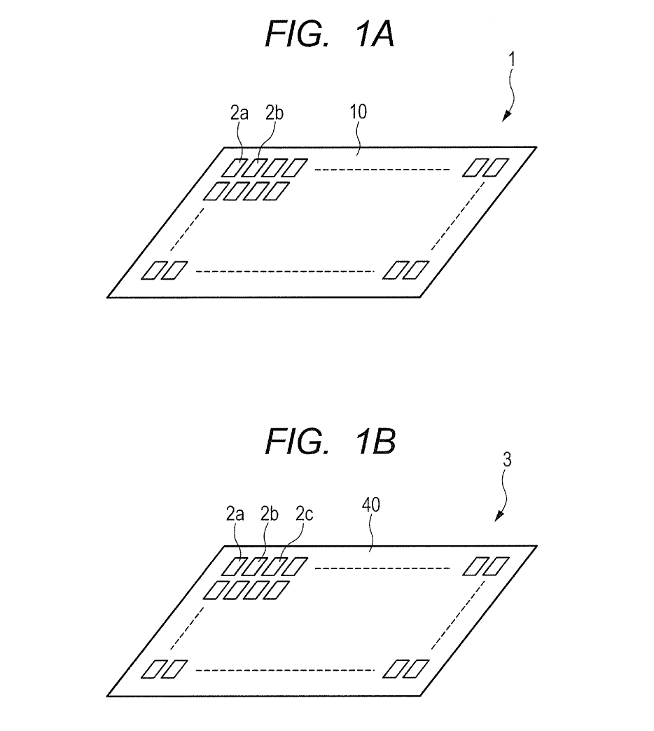

FIGS. 1A and 1B are perspective views illustrating specific examples of an organic EL display device manufactured by the manufacturing method according to the present invention. In an organic EL display device 1 illustrated in FIG. 1A, two kinds of pixels, that is, first pixels 2a and second pixels 2b, which emit light of different colors, are arranged in matrix on a substrate 10. On the other hand, in an organic EL display device 3 illustrated in FIG. 1B, three kinds of pixels, that is, the first pixels 2a, the second pixels 2b, and third pixels 2c, which emit light of different colors, are arranged in matrix on a substrate 40. Note that, the two examples illustrated in FIGS. 1A and 1B are only specific examples, and the present invention is not limited to the examples illustrated in FIGS. 1A and 1B.

Next, a manufacturing process of each of the organic EL display device 1 illustrated in FIG. 1A and the organic EL display device 3 illustrated in FIG. 1B is described in detail.

### First Embodiment

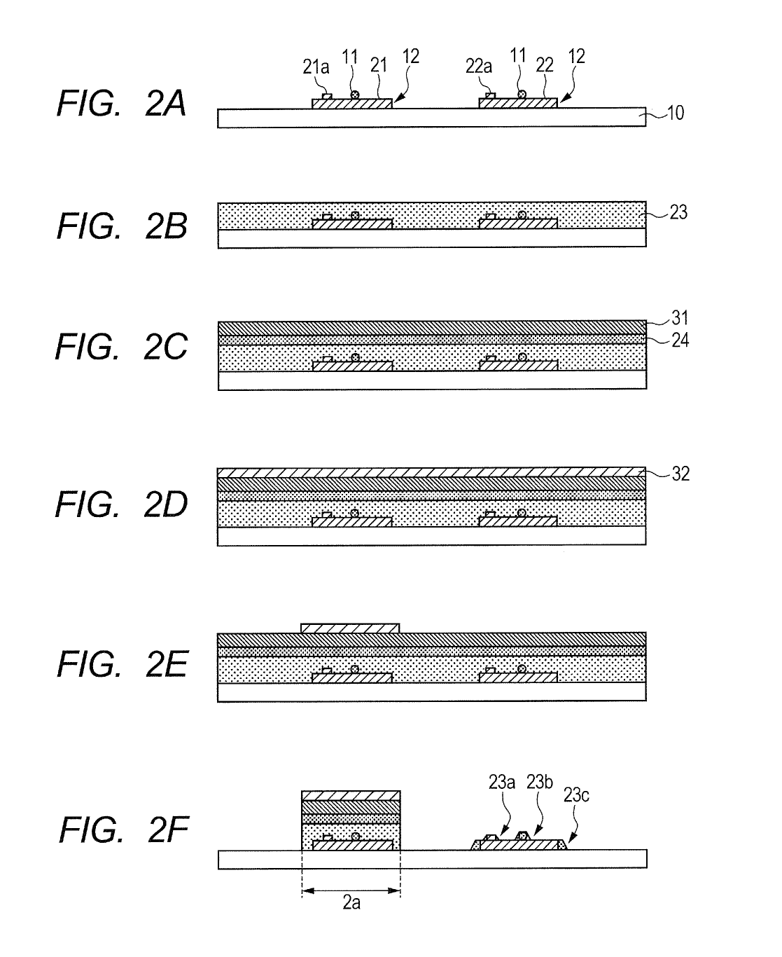

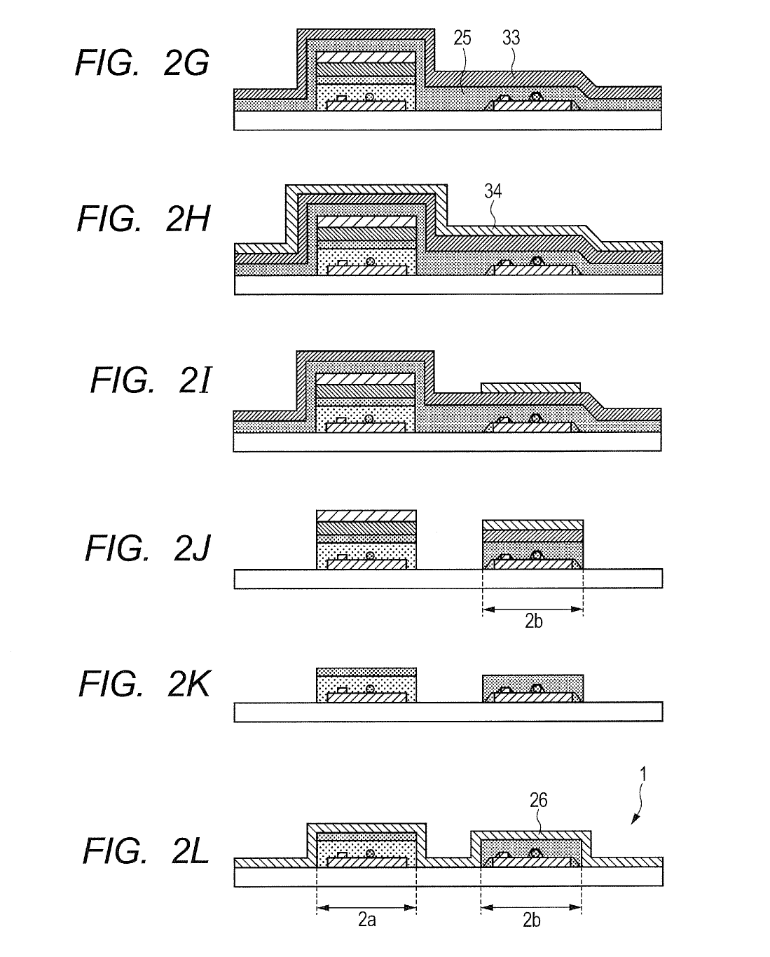

FIGS. 2A to 2L are schematic sectional views illustrating an organic EL display device according to a first embodiment of the present invention. Further, FIGS. 2A to 2L are a specific example of the manufacturing process of the organic EL display device 1 illustrated in FIG. 1A. The method of manufacturing an organic EL display device according to the first embodiment of the present invention is described in the following with reference to FIGS. 2A to 2L.

(1-1) Substrate

First, a substrate with electrodes illustrated in FIG. 2A is prepared. The substrate 10 which forms the substrate with electrodes is not specifically limited insofar as the substrate 10 enables stable manufacture of the organic EL display device, and, for example, glass or an Si wafer may be used as the substrate 10.

Note that, a drive circuit for driving the organic EL display device such as a transistor may be provided in the substrate 10 as necessary. When a drive circuit is provided in the substrate 10, for the purpose of planarizing surfaces of the substrate 10 and a lower electrode, a planarized passivation film may be provided.

With regard to the substrate with electrodes illustrated in FIG. 2A, two kinds of electrodes, that is, a first pixel electrode 21 and a second pixel electrode 22, are provided on the substrate 10. In this case, the first pixel electrode 21 is a lower electrode which forms the first pixel 2a in FIG. 1A, while the second pixel electrode 22 is a lower electrode which forms the second pixel 2b in FIG. 1A. Note that, as illustrated in FIG. 2A, the first pixel electrode 21 and the second pixel electrode 22 are electrodes which are independent of each other. As a constituent material of the first pixel electrode 21 and the second pixel electrode 22, a conductive material which may be patterned by a publicly-known method may be used. For example, a metal material such as Al or Ag or a transparent electrode material such as indium tin oxide or indium zinc oxide may be used. Note that, a laminated electrode film formed by laminating a thin film formed of the above-mentioned metal material and a thin film formed of the above-mentioned transparent electrode material may also be used.

By the way, although not illustrated in FIG. 2A, according to the present invention, a pixel separation film for separating the first pixel electrode 21 and the second pixel electrode 22 may be provided as necessary.

On the other hand, when the substrate with electrodes illustrated in FIG. 2A is prepared, surfaces of the electrodes 21 and 22 provided on the substrate with electrodes are already cleaned and surface-treated, but there are cases in which grains 21a and 22a of an electrode material or a foreign matter 11 such as a residue of a resist used in patterning the electrodes remains. Further, when the electrodes 21 and 22 are formed, a level difference 12 by the amount of the thickness of the electrodes develops. The grains 21a and 22a of the electrode material, the foreign matter 11, and the level difference 12 described above are causes of development of a layer defect when an organic compound layer is formed. Therefore, steps described in the following are carried out.

(1-2) Step of Forming Charge Injection Transport Layer

Next, as illustrated in FIG. 2B, a charge injection transport layer 23 which also functions as a covering layer for covering a foreign matter or the like is formed on the substrate 10, the first pixel electrode 21, and the second pixel electrode 22. In this case, according to the present invention, the charge injection transport layer 23 is formed by a forming method capable of covering up the portion to be concealed. “Covering up” as used herein means how much the charge injection transport layer formed on the pixel electrodes 21 and 22 is formed by entering a portion of shadow of unevenness when there is unevenness, for example, the grains 21a and 22a or the foreign matter 11 exists on the surfaces of the pixel electrodes 21 and 22 or the level difference 12 exists which is developed when the pixel electrodes 21 and 22 are formed. In other words, the “covering up” also means “coverage” showing how much the film is formed along the surface of unevenness. The method capable of covering up the portion to be concealed is a method in which the charge injection transport layer can be formed even at a portion of shadow of the unevenness. That is, the method is a method in which the surface of the unevenness can be covered up with high coverage. Exemplary forming methods capable of covering up the portion to be concealed include an applying method in which a liquid having a material to be a film is dissolved therein in advance is applied and dried, angle vapor deposition that is carried out under a state in which the direction of the vapor deposition and the substrate relatively forms an angle, and vapor deposition that is carried out under a state in which a film is formed under low vacuum conditions at the pressure of 0.1 Pa to 10 Pa in which the mean free path is short. As described above, there are cases in which the grains 21a and 22a of the electrode material or the foreign matter 11 develop on the surfaces of the pixel electrodes 21 and 22. Further, there are cases in which the level difference 12 or the like develops on the periphery of the pixel electrodes 21 and 22 when the pixel electrodes are formed. By using the above-mentioned forming method capable of covering up the portion to be concealed, the charge injection transport material may go into the bases of the grains 21a and 22a of the electrode material, of the foreign matter 11, and of the level difference 12, and portions in the shadow developed thereby.

A constituent material of the charge injection transport layer 23 is not specifically limited insofar as the material has the function of transporting charge (holes or electrons) injected from the first pixel electrode 21 to a first organic compound layer 24 to be formed in the next step. For example, a conductive polymer such as polypyrrole, polyaniline, or polythiophene may be used. When the above-mentioned conductive polymer is used in this case, by dispersing the polymer in an organic solvent and application thereof by spin coating, printing, the ink jet method, or the like, a layer may be formed.

(1-3) Step of Forming First Organic Compound Layer

Next, as illustrated in FIG. 2C, the first organic compound layer 24 is formed. The first organic compound layer 24 is a layer or a laminate including multiple layers and at least includes an emission layer. When the first organic compound layer 24 includes multiple layers, exemplary layers other than the emission layer include a hole transport layer, a hole injection layer, an electron transport layer, and an electron injection layer.

As a constituent material of the first organic compound layer 24, a publicly-known low molecule-based material or high molecule-based material may be selected and used as appropriate. Further, as the method of forming the first organic compound layer 24, a publicly-known thin film forming method such as vapor deposition may be used.

(1-4) Step of Forming First Resist-Resistant Protective Layer

After the first organic compound layer 24 is formed, a first resist layer 32 to be described later may be directly formed on the first organic compound layer (on the first organic compound layer 24), but, alternatively, a first resist-resistant protective layer 31 may be provided on the first organic compound layer 24 before the first resist layer 32 is formed. The first resist-resistant protective layer 31 has the function of, when the first resist layer 32 is formed thereon, preventing the first organic compound layer 24 from being dissolved or altered by a solvent for dissolving the resist material. As the first resist-resistant protective layer, a layer which is highly resistant to moisture is preferred so that the solvent contained in the resist material does not penetrate the first organic compound layer, and a layer formed of SiN, SiON, Si, SiO₂, or a mixture thereof is suitable. However, when a material which does not adversely affect the first organic compound layer such as a water-soluble one is adopted as the resist material, the first resist-resistant protective layer 31 is not necessarily required.

(1-5) Step of Forming First Resist Layer

Then, as illustrated in FIG. 2D, the first resist layer 32 is formed on the first resist-resistant protective layer 31. Note that, as described above, the first resist layer 32 may be directly formed on the first organic compound layer 24. When the first resist layer 32 is directly formed on the first organic compound layer 24, it is preferred that a material which satisfies the following conditions (1-5a) and (1-5b) be selected as a constituent material of the first resist layer 32.

(1-5a) Being a material which is dissolved in a solvent in which the first organic compound layer 24 is not dissolved.

(1-5b) Being a material which does not damage the first organic compound layer 24 when the first resist layer 32 is formed.

Exemplary resist materials which are dissolved in a solvent in which the first organic compound layer 24 is not dissolved include water-soluble polymers such as polyvinyl alcohol (PVA) and polyvinyl pyrrolidone. Further, a resist material which is dissolved in an organic solvent such as a novolac resin may also be used, but, when a resist material which is dissolved in an organic solvent is used, it is preferred to provide the above-mentioned first resist-resistant protective layer 31 before the first resist layer 32 is formed.

(1-6) Step of Processing First Organic Compound Layer and Charge Injection Transport Layer

Next, the first organic compound layer 24 and the charge injection transport layer 23 are processed. In processing the first organic compound layer 24 and the charge injection transport layer 23, for example, photolithography may be used. When photolithography is used to process the first organic compound layer 24, specific steps thereof are the following (1-6a) and (1-6b).

(1-6a) Developing step (FIG. 2E)

(1-6b) Etching step (FIG. 2F)

When patterning is carried out using photolithography (using photolithography and dry etching in combination) as in these steps, after the first resist layer 32 is formed, exposure is carried out, and a solvent is used to partially remove an exposed region or an unexposed region. In this way, a pattern of the first resist layer 32 is obtained (FIG. 2E). Note that, the pattern of the first resist layer 32 corresponds to a region in which the first pixel 2a illustrated in FIG. 1A is provided.

On the other hand, when the ink jet method, printing, or the like is used, it is possible to form the first resist layer 32 in the shape of a desired pattern without carrying out the above-mentioned developing step (1-6a). In this way, when the first resist layer 32 is formed in the shape of a desired pattern using the ink jet method, printing, or the like, the above-mentioned developing step may be omitted and the next step (etching step) may be carried out.

After the pattern of the first resist layer 32 is formed, etching is carried out to selectively remove the first organic compound layer 24 and the charge injection transport layer 23 formed in a region in which the first resist layer 32 is not left (FIG. 2F). In other words, in the step of processing the first organic compound layer 24, the first organic compound layer 24 is removed except for the region in which the first pixel 2a illustrated in FIG. 1A is provided. In this case, as a specific method of selectively removing (patterning) the first organic compound layer 24, for example, dry etching may be used. Alternatively, instead of dry etching, a method of selectively removing the first organic compound layer 24 using laser or the like (physically removing method) may be used.

By the way, when the etching step is carried out, the charge injection transport layer 23 provided on the second pixel electrode 22 is basically removed. However, in the manufacturing method according to the present invention, the charge injection transport layer 23 goes into portions in the shadow developed by the grain 22a of the electrode material and the foreign matter 11, which may exist on the surface of the second pixel electrode 22, and developed by the electrode level difference 12 developed when the second pixel electrode is formed. By carrying out the etching step to remove the charge injection transport layer 23 provided on the second pixel electrode 22 at this point, the charge injection transport layer in the portions in the shadow developed by the grain 22a, the foreign matter 11, and the level difference 12 (23a, 23b, and 23c) remain as it is without being removed (FIG. 2F). By leaving the charge injection transport layer in the portions in the shadow developed by the grain 22a, the foreign matter 11, and the level difference 12 denoted as reference symbols 23a to 23c in FIG. 2F, the following effect is brought about. When a second organic compound layer 25 and a counter electrode 27 are formed on the second pixel electrode 22 in subsequent steps, film defects which may occur by the existence of the portions in the shadow developed by the grain 22a, the foreign matter 11, and the level difference 12 may be prevented before those occur.

Note that, the grain 22a of the electrode material, the foreign matter 11, and the electrode level difference 12 illustrated in FIGS. 2A to 2F are exaggerated for the sake of convenience of description. The actual sizes of the grain 22a of the electrode material and the foreign matter 11 and the electrode level difference 12 are, in reality, as small as 10 nm to 100 nm. However, these may be, when an organic compound layer is formed, causes of occurrence of film defects of a film to become the organic compound layer. Therefore, according to the present invention, from the viewpoint of preventing occurrence of film defects, the charge injection transport material is filled in the portions in the shadow developed by the grain 22a of the electrode material, the foreign matter 11, and the electrode level difference 12.

(1-7) Step of Forming Second Organic Compound Layer

Next, as illustrated in FIG. 2G, the second organic compound layer 25 is formed at least on the second pixel electrode 22. The second organic compound layer 25 is a layer or a laminate including multiple layers and at least includes an emission layer. When the second organic compound layer 25 includes multiple layers, exemplary layers other than the emission layer include a hole transport layer, a hole injection layer, an electron transport layer, and an electron injection layer.

As a constituent material of the second organic compound layer 25, similarly to the case of the first organic compound layer 24, a publicly-known low molecule-based material or high molecule-based material may be selected as appropriate. Note that, when the color of light emitted from the first pixel and the color displayed by the second pixel are different from each other, as an emission material contained in the emission layer forming the second organic compound layer 25, there is used one having an emission spectrum which is different from that of an emission material contained in the emission layer forming the first organic compound layer 24. Alternatively, the thickness of the first organic compound layer and the thickness of the second organic compound layer may be set to be different from each other so that the colors displayed by the first pixel and the second pixel are different from each other utilizing interference of light.

(1-8) Step of Forming Second Resist-Resistant Protective Layer and Second Resist Layer

After the second organic compound layer 25 is formed, as illustrated in FIGS. 2G to 2I, a second resist-resistant protective layer 33 and a second resist layer 34 are formed in sequence on the second organic compound layer 25. Note that, the second resist layer 34 may be directly formed on the second organic compound layer 25, but, as illustrated in FIG. 2G, the second resist-resistant protective layer 33 may be provided on the second organic compound layer 25 before the second resist layer 34 is formed. When the second resist-resistant protective layer 33 and the second resist layer 34 are formed, as constituent materials thereof, materials similar to those of the first resist-resistant protective layer 31 and the first resist layer 32, respectively, may be used. Note that, when a material which does not adversely affect the second organic compound layer 25 is adopted as the resist material which is a constituent material of the second resist layer 34, as illustrated in FIG. 2H, the second resist layer 34 may be formed under a state in which the formation of the second resist-resistant protective layer 33 is omitted. When the second resist layer 34 is formed under a state in which the formation of the second resist-resistant protective layer 33 is omitted, it is more preferred that a material which does not adversely affect the second organic compound layer 25 be adopted as the resist material which is a constituent material of the second resist layer 34.

(1-9) Step of Processing Second Organic Compound Layer

Next, as illustrated in FIG. 2I, the second resist layer 34 is patterned, and after that, as illustrated in FIG. 2J, the second organic compound layer 25 is processed to be partially removed. With regard to the patterning of the second resist layer 34 and the partial removal of the second organic compound layer 25, a method similar to the methods described in the above-mentioned step of processing the first organic compound layer 24 (dry etching and the like) may be adopted. In this step of processing the second organic compound layer 25, the second organic compound layer 25 is removed except for a region in which the second pixel 2b illustrated in FIG. 1A is provided.

(1-10) Step of Removing Resist-Resistant Protective Layer and Resist Layer

Next, as illustrated in FIG. 2K, the resist layers and the resist-resistant protective layers provided on the organic compound layers 24 and 25 are removed. In this case, as a method of removing the resist layers 32 and 34 the resist-resistant protective layers 31 and 33, for example, dry etching may be adopted.

(1-11) Step of Forming Counter Electrode

Next, as illustrated in FIG. 2L, a counter electrode 26 is formed on the first organic compound layer 24 and the second organic compound layer 25, thereby completing the organic EL display device 1. In this case, the counter electrode 26 is an electrode common to the first pixel 2a including the first pixel electrode 21, the charge injection transport layer 23, and the first organic compound layer 24 and the second pixel 2b including the second pixel electrode 22 and the second organic compound layer 25, and functions as an upper electrode.

A constituent material of the counter electrode 26 is not specifically limited insofar as the material is a conductive material which does not damage the organic compound layers 24 and 25 when the counter electrode 26 is formed. For example, a metal material such as Al or Ag or a transparent electrode material such as indium tin oxide or indium zinc oxide may be used. A laminate formed by laminating a thin film formed of a metal material and a thin film formed of a transparent electrode material may also be used. In this case, in order to take out light emitted from the organic compound layers 24 and 25, a transparent or translucent material is used for at least one of the pixel electrodes 21 and 22 and the counter electrode 26.

(1-12) Step of Forming Common Layer

Note that, before the counter electrode 26 is formed, a common layer (not shown) common to the first pixel and the second pixel may be formed on the first organic compound layer 24 and the second organic compound layer 25. In this case, the common layer is formed of a layer or multiple layers, and is provided for the purpose of transporting charge (holes or electrons) injected from the counter electrode 26 to the organic compound layers (emission layers therein). Exemplary specific layers to be included in the common layer include a hole transport layer, a hole injection layer, an electron transport layer, and an electron injection layer.

(1-13) Encapsulating Step

After the counter electrode 26 is formed, an encapsulating part (not shown) may be provided for the purpose of preventing oxygen and moisture in the atmosphere from entering the organic compound layers 24 and 25 included in the organic EL display device 1. The encapsulating part may be provided by publicly-known methods including a method in which an encapsulating film made of SiN, SiO, or the like is formed, and a method in which the substrate 10 and a counter substrate are bonded together and the periphery is fixed with a resin, glass frit, or the like.

In this case, a region in which the organic compound layers 24 and 25 and the common layer are provided may be defined by a rough mask or the like to partially provide a region in which the organic compound layers 24 and 25 and the common layer are not formed, that is, an organic layer non-formation region. By coverage up to the organic layer non-formation region with an encapsulating film or by bonding the substrate 10 to the counter substrate in the organic layer non-formation region, a path through which moisture may enter may be blocked with more reliability.

As described above, the organic EL display device 1 is obtained which includes the first pixel 2a having the first pixel electrode 21 and the first organic compound layer 24 and the second pixel 2b having the second pixel electrode 22 and the second organic compound layer 25 and which may display a color image under a state in which each pixel independently emits light.

### Second Embodiment

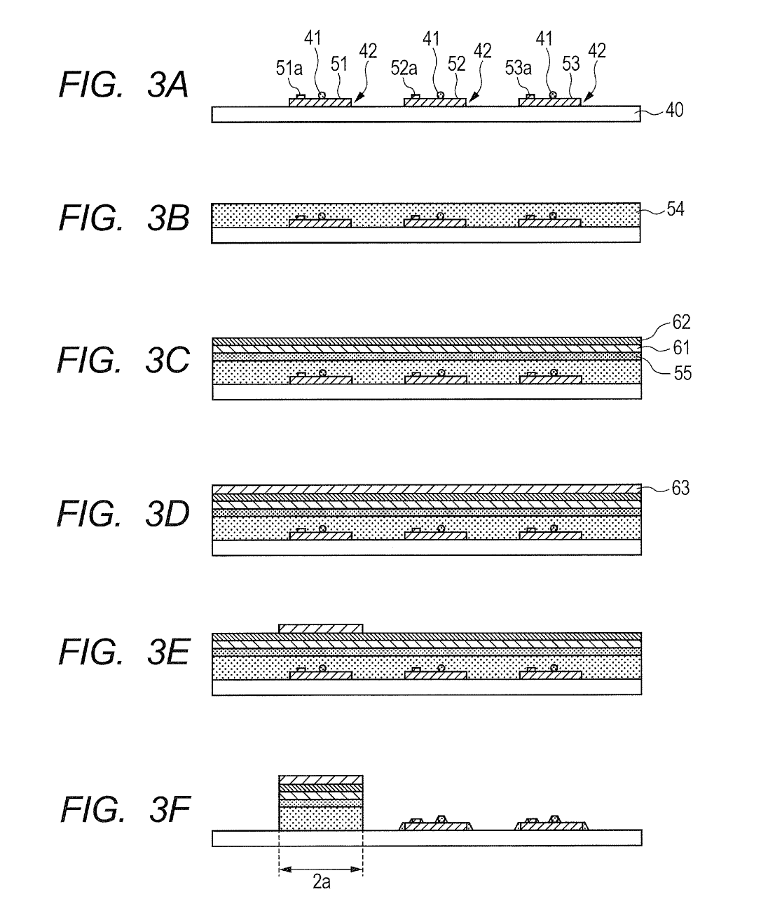

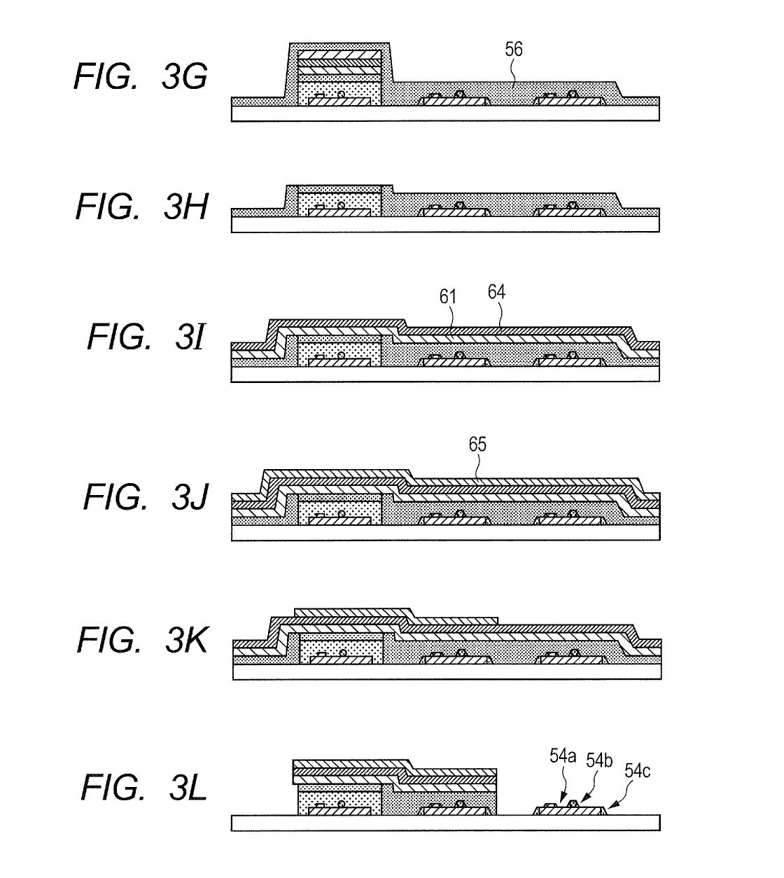

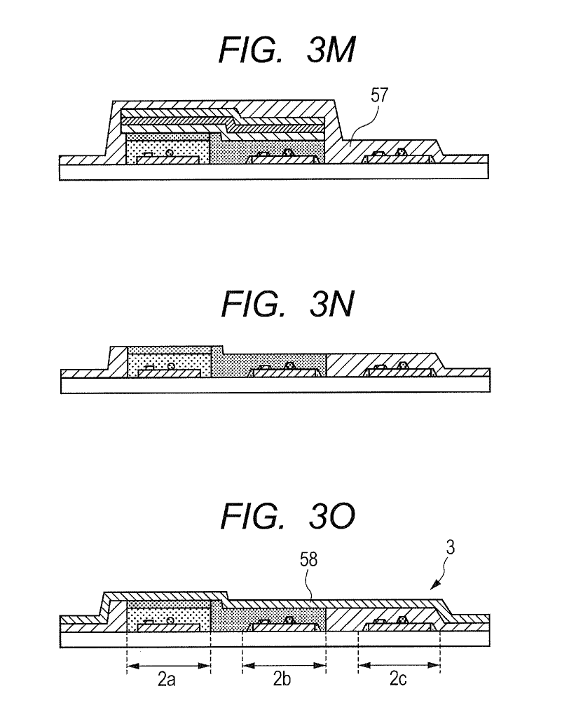

FIGS. 3A to 3O are schematic sectional views illustrating a method of manufacturing an organic EL display device according to a second embodiment of the present invention. Further, FIGS. 3A to 3O are a specific example of the manufacturing process of the organic EL display device 3 illustrated in FIG. 1B. The method of manufacturing an organic EL display device according to the second embodiment of the present invention is described in the following with reference to FIGS. 3A to 3O. Note that, in the following, differences from the first embodiment are mainly described.

(2-1) Substrate

First, a substrate with electrodes is prepared (FIG. 3A). Note that, in the substrate with electrodes illustrated in FIG. 3A, the substrate 40 and pixel electrodes (a first pixel electrode 51, a second pixel electrode 52, and a third pixel electrode 53) provided on the substrate are formed in regions in which the first pixel 2a, the second pixel 2b, and the third pixel 2c are formed, respectively, in FIG. 1B.

(2-2) Step of Forming Charge Injection Transport Layer

Next, a charge injection transport layer 54 is formed (FIG. 3B). Note that, with regard to a material and a layer forming method which are used when the charge injection transport layer 54 is formed, ones similar to those of the first embodiment may be adopted, but the present invention is not limited thereto.

By the way, in this embodiment, similarly to the case of the first embodiment, the charge injection transport layer 54 is formed by a forming method capable of covering up the portion to be concealed. This may enable a constituent material of the charge injection transport layer to go into the bases of grains (51a, 52a, and 53a) of the electrode material and a foreign matter 41, if any, on surfaces of the pixel electrodes 51, 52, and 53, and portions in the shadow developed thereby. Further, even when a level difference 42 or the like is developed when the pixel electrodes 51, 52, and 53 are formed, a constituent material of the charge injection transport layer may be caused to go into the bases of the level difference 42 and portions in the shadow developed thereby.

(2-3) Step of Forming First Organic Compound Layer

Next, a first organic compound layer 55 is formed (FIG. 3C). In this embodiment, with regard to a material and a layer forming method which are used when the first organic compound layer 55 is formed, ones described in the first embodiment may be adopted, but the present invention is not limited thereto.

(2-4) Step of Forming First Resist-Resistant Protective Layer

Next, a first resist-resistant protective layer 62 is formed (FIG. 3C). Note that, when the first resist-resistant protective layer 62 is formed, an intermediate layer 61 for releasing the first resist-resistant protective layer 62 from the first organic compound layer 55 may be provided between the first organic compound layer 55 and the first resist-resistant protective layer 62 as illustrated in FIG. 3C. As the intermediate layer 61, a water-soluble polymer such as polyvinyl alcohol (PVA) or polyvinyl pyrrolidone containing a solvent which does not dissolve the first organic compound layer 55 may be used. Further, as a constituent material of the first resist-resistant protective layer 62, one similar to those described in the first embodiment may be used. The method in which the intermediate layer is provided between the organic compound layer and the resist-resistant protective layer may also be applied to the first embodiment.

(2-5) Step of Forming First Resist Layer

Next, a first resist layer 63 is formed (FIG. 3D). In this embodiment, when the first resist layer 63 is formed, the methods described in the first embodiment may be adopted.

(2-6) Step of Processing First Organic Compound Layer

Next, after a step of developing the first resist layer 63 is carried out (FIG. 3E), the first organic compound layer 55 is processed (FIG. 3F). In this embodiment, when the first organic compound layer 55 is processed, the methods described in the first embodiment, for example, dry etching, may be adopted.

By this step of processing the first organic compound layer 55, the first organic compound layer 55 is selectively formed only in a region in which the first pixel 2a illustrated in FIG. 1B is provided (FIG. 3F).

(2-7) Step of Forming Second Organic Compound Layer

Next, a second organic compound layer 56 is formed on an entire surface (FIG. 3G). Note that, in this embodiment, as illustrated in FIG. 3G, the second organic compound layer 56 is formed over an entire display region. In this embodiment, with regard to a material and a layer forming method which are used when the second organic compound layer 56 is formed, ones similar to those of the case of the first organic compound layer 55 described above may be adopted, but the present invention is not limited thereto.

(2-8) Step of Processing Second Organic Compound Layer

Next, a step of processing the second organic compound layer 56 is carried out. In this embodiment, the following steps (2-8a) and (2-8b) are carried out to process the second organic compound layer 56:

(2-8a) removing the second organic compound layer 56 provided on the first organic compound layer 55 (FIG. 3H); and

(2-8b) removing the second organic compound layer 56 provided on the third pixel electrode 53 (FIGS. 3I to 3L).

First, when the second organic compound layer 56 provided on the first organic compound layer 55 is removed as illustrated in FIG. 3H, the intermediate layer 61 provided on the first organic compound layer 55 is, for example, immersed in water and then dissolved in water. This enables lift-off of the multiple layers provided on the intermediate layer 61, that is, the first resist-resistant protective layer 62, the first resist layer 63, and the second organic compound layer 56 from the first organic compound layer 55.

Next, when the second organic compound layer 56 provided on the third pixel electrode 53 is removed, for example, the following steps are carried out:

(2-8b-1) forming an intermediate layer 61 and a second resist-resistant protective layer 64 (FIG. 3I);

(2-8b-2) forming a second resist layer 65 (FIG. 3J);

(2-8b-3) developing the second resist layer 65 (FIG. 3K); and

(2-8b-4) selectively removing the second resist-resistant protective layer 64, the intermediate layer 61, and the second organic compound layer 56 (processing second organic compound layer, FIG. 3L).

In this case, the intermediate layer 61 illustrated in FIG. 3I is similar to the intermediate layer 61 illustrated in FIG. 3C. Further, the second resist-resistant protective layer 64 illustrated in FIG. 3I has the function of, when the second resist layer 65 is formed in the next step, preventing the first organic compound layer 55 and the second organic compound layer 56 from being dissolved or altered. Note that, when a solvent in which a constituent material of the second resist layer 65 is dissolved is not a solvent in which a constituent material of the first organic compound layer 55 and the second organic compound layer 56 is dissolved, the step of forming the second resist layer 65 may be carried out under a state in which the step of forming the intermediate layer 61 and the second resist-resistant protective layer 64 is omitted.

When the second resist layer 65 is developed as illustrated in FIG. 3K, a method which is similar to that used in the above-mentioned step of developing the first resist layer may be adopted. Further, when the second organic compound layer 56 is processed (partially removed) as illustrated in FIG. 3L, a processing method such as dry etching may be adopted.

By the way, by carrying out the step of processing the second organic compound layer 56, the second organic compound layer 56 provided on the third pixel electrode 53 is removed. In this case, a part of the charge injection transport layer (54a, 54b, and 54c) remains in portions in the shadow which are developed by the existence of a grain 53a of the electrode material and the foreign matter 41 on a surface of the third pixel electrode 53 and by the development of the level difference 42 when the third pixel electrode 53 is formed. This may prevent occurrence of film defects when a third organic compound layer 57 and a counter electrode 58 described below are formed on the third pixel electrode 53.

(2-9) Step of Forming Third Organic Compound Layer

Next, as illustrated in FIG. 3M, the third organic compound layer 57 is formed at least on the third pixel electrode 53. The third organic compound layer 57 may be formed by, for example, vacuum deposition.

(2-10) Step of Processing Third Organic Compound Layer

Next, a step of processing the third organic compound layer is carried out (FIG. 3N). Specifically, this step is carried out by immersing and dissolving the intermediate layer 61 in a solvent such as water. This method enables collective lift-off of the second resist-resistant protective layer 64 and the second resist layer formed on the intermediate layer 61 and the third organic compound layer 57 formed on the second resist layer 65 from the first organic compound layer 55 and the second organic compound layer 56.

(2-11) Step of Forming Counter Electrode

Next, as illustrated in FIG. 3O, by forming the counter electrode 58 on the first organic compound layer 55, on the second organic compound layer 56, and on the third organic compound layer 57, the organic EL display device 3 is completed. In this case, the counter electrode 58 is an electrode common to the three kinds of pixels (the first pixel 2a, the second pixel 2b, and the third pixel 2c) illustrated in FIG. 1B, and functions as an upper electrode. Note that, when the counter electrode 58 is formed, a method similar to that of the first embodiment may be adopted.

(2-12) Encapsulating Step and the Like

In this embodiment, also, similarly to the case of the first embodiment, an encapsulating part for preventing oxygen and moisture in the atmosphere from entering the organic compound layers included in the organic EL display device may be provided.

As described above, the organic EL display device is obtained in which the first organic compound layer 55 emits light on the first pixel electrode 51, the second organic compound layer 56 emits light on the second pixel electrode 52, and the third organic compound layer 57 emits light on the third pixel electrode 53 and which may display a color image.

In the following, the method of manufacturing an organic EL device according to the present invention is described by means of examples. However, the present invention is not limited to the examples described in the following.

### Example 1

The manufacturing process illustrated in FIGS. 2A to 2L were used to manufacture the organic EL display device 1 illustrated in FIG. 1A.

(1) Step of Forming Pixel Electrode

First, by sputtering, an aluminum film and an indium zinc oxide film were formed in this order on the glass substrate 10 to form a laminated electrode film. In this case, the thickness of the aluminum film was 200 nm and the thickness of the indium zinc oxide film was 20 nm. Then, by processing (patterning) the laminated electrode film formed earlier using a photolithography process, the two kinds of electrodes illustrated in FIG. 2A, that is, multiple first pixel electrodes 21 and multiple second pixel electrodes 22 were formed. Note that, the width of each of the first pixel electrode 21 and the second pixel electrode 22 was 50 μm and the space between the pixel electrodes was 5 μm. Then, a pixel separation film (not shown) of a polyimide resin was formed at a thickness of 2 μm between the first pixel electrode 21 and the second pixel electrode 22.

(2) Step of Forming Charge Injection Transport Layer

Next, 0.5 ml of a water dispersion of poly(3,4-ethylenedioxythiophene)/polystyrene sulfonate (PEDOT/PSS) (Baytron P CH8000 manufactured by H. C. Starck GmbH) was taken out. The water dispersion of PEDOT/PSS which was taken out was dropped onto a center portion of the substrate 10 and spin coating was carried out by rotating the substrate 10 for 20 seconds at the speed of 2,500 rpm. This formed a PEDOT/PSS film on the substrate 10 and the pixel electrodes 21 and 22. Then, by carrying out drying at 150° C. for 10 minutes, the charge injection transport layer 23 was formed (FIG. 2B). In this case, the thickness of the charge injection transport layer 23 was 80 nm. Note that, in this step, the charge injection transport layer 23 was formed over the entire surface of the display region on the substrate 10.

(3) Step of Forming First Organic Compound Layer

Then, a hole injection layer, a hole transport layer, and an emission layer were formed in this order on the charge injection transport layer 23 by vacuum deposition. In this case, a laminate including the hole injection layer, the hole transport layer, and the emission layer formed in this step functions as the first organic compound layer 24. Note that, in this example, the thickness in total of the first organic compound layer 24 was 200 nm, and, as the emission material included in the emission layer, an emission material for yellow light emission was used. Further, constituent materials of the layers included in the first organic compound layer 24 (the hole injection layer, the hole transport layer, and the emission layer) were publicly-known organic low molecular materials.

(4) Step of Forming First Resist-Resistant Protective Layer

Then, an SiN film was formed on the first organic compound layer 24 by plasma CVD to form the first resist-resistant protective layer 31 (FIG. 2C). In this case, the thickness of the first resist-resistant protective layer 31 was 1 μm.

(5) Step of Forming First Resist Layer

Then, a positive type photoresist was applied onto the first resist-resistant protective layer 31. By forming a film by spin coating and carrying out drying, the first resist layer 32 was formed (FIG. 2D).

(6) Developing Step

Then, by carrying out exposure and development in a predetermined pattern using a mask exposure system, the pattern of the first resist layer 32 was formed in a region corresponding to the first pixel 2a (FIG. 2E).

(7) Step of Processing First Organic Compound Layer

Then, the first resist-resistant protective layer 31, the first organic compound layer 24, and the charge injection transport layer 23 provided in the region in which the first resist layer 32 had been removed were removed by a method described in the following (FIG. 2F).

By carrying out dry etching with use of the remaining first resist layer 32 as a mask, the first resist-resistant protective layer 31, the first organic compound layer 24, and the charge injection transport layer 23 were removed in sequence. In this case, an RIE system was used as the dry etching system, and a gas mixture of CF₄ and O₂ was used as the etching gas.

(8) Step of Forming Second Organic Compound Layer

Then, a hole injection layer, a hole transport layer, and an emission layer were formed in this order over the entire surface of the display region on the substrate 10. In this case, a laminate including the hole injection layer, the hole transport layer, and the emission layer formed in this step functions as the second organic compound layer 25. Note that, in this example, the thickness in total of the second organic compound layer 25 was 150 nm, and, as the emission material included in the emission layer, an emission material for blue light emission was used. Further, constituent materials of the layers included in the second organic compound layer 25 (the hole injection layer, the hole transport layer, and the emission layer) were publicly-known organic low molecular materials.

(9) Step of Forming Second Resist-Resistant Protective Layer

Then, an SiN film was formed on the second organic compound layer 25 by plasma CVD to form the second resist-resistant protective layer 33 (FIG. 2G). In this case, the thickness of the second resist-resistant protective layer 33 was 1 μm.

(10) Step of Forming Second Resist Layer

Then, a positive type photoresist was applied onto the second resist-resistant protective layer 33. By forming a film by spin coating and carrying out drying, the second resist layer 34 was formed (FIG. 2H).

(11) Developing Step

Then, by carrying out exposure and development in a predetermined pattern using a mask exposure system, the pattern of the second resist layer 33 was formed in a region corresponding to the second pixel 2b (FIG. 2I).

(12) Step of Processing Second Organic Compound Layer

Then, the second resist-resistant protective layer 33 and the second organic compound layer 25 provided in the region in which the second resist layer 34 had been removed were removed by a method described in the following (FIG. 2J).

By carrying out dry etching with use of the remaining second resist layer 34 as a mask, the second resist-resistant protective layer 33 and the second organic compound layer 25 were removed in sequence. In this case, an RIE system was used as the dry etching system, and an O₂ gas was used as the etching gas.

(13) Step of Removing Resist Layer and Resist-Resistant Protective Layer

Then, the first resist-resistant protective layer and the first resist layer 32 provided on the first pixel electrode 21 and the second resist-resistant protective layer 33 and the second resist layer 34 provided on the second pixel electrode 22 were removed by a process described in the following (FIG. 2K).

By dry etching using an RIE system and a CF₄ gas (etching gas), the resist layers 32 and 34 were removed. Then, by dry etching in the presence of low pressure and high frequency electric power at the pressure of 10 Pa and the electric power of 70 W/m², the resist-resistant protective layers 31 and 33 were removed. In this example, in the above-mentioned process, the etching rates of the resist-resistant protective layers of an inorganic material and the etching rates of the organic emission layers are different from each other, and thus, selective etching may be carried out.

(14) Step of Forming Counter Electrode

Then, the counter electrode 26 which was an electrode common to the first pixel 2a and the second pixel 2b was formed on the first organic compound layer 24 and the second organic compound layer 25 by a method described in the following (FIG. 2L).

An Ag film was formed by sputtering on the first organic compound layer 24 and the second organic compound layer 25 to form the counter electrode 26. In this case, the thickness of the counter electrode 26 was 20 nm.

(15) Encapsulating Step

Finally, an SiN film was formed on the counter electrode 26 by CVD to form an encapsulating film (not shown) for preventing moisture from entering the organic compound layers 24 and 25. In this case, the thickness of the encapsulating film was 2,000 nm.

As described above, the organic EL display device having two kinds of emission colors (yellow and blue) was obtained. Note that, in the organic EL display device manufactured in this example, predetermined organic compound layers were arranged on predetermined pixel electrodes with high accuracy. Further, when the manufactured organic EL display device was caused to emit light, no defective light emission was observed.

### Example 2

The manufacturing process illustrated in FIGS. 3A to 3O were used to manufacture the organic EL display device 3 illustrated in FIG. 1B.

(1) Step of Forming Pixel Electrode

First, by the method similar to the method described in Example 1, an aluminum film and an indium zinc oxide film were formed in this order on the glass substrate 40 to form a laminated electrode film. Then, by processing (patterning) the laminated electrode film formed earlier using a photolithography process, the three kinds of electrodes illustrated in FIG. 3A, that is, multiple first pixel electrodes 51, multiple second pixel electrodes 52, and multiple third pixel electrodes 53 were formed. Note that, the width of each of the first pixel electrode 51, the second pixel electrode 52, and the third pixel electrode 53 was 50 μm and the space between the pixel electrodes was 5 μm. Then, a pixel separation film (not shown) of a polyimide resin was formed at a thickness of 2 μm between the pixel electrodes adjacent to each other.

(2) Step of Forming Charge Injection Transport Layer

Then, a polypyrrole film was formed on the substrate 40 and the pixel electrodes 51, 52, and 53 by angle vapor deposition to form the charge injection transport layer 54 (FIG. 3B). In this case, the thickness of the charge injection transport layer 54 was 100 nm. Note that, the angle vapor deposition which was carried out in this step is a method of forming a thin film in which vapor deposition is carried out under a state in which the substrate 40 rotates while tilting its axis by 40°, and is a film forming method in which a film may be formed with covering up the portion to be concealed. Further, in this step, the charge injection transport layer 54 was formed over the entire display region on the substrate 40.

(3) Step of Forming First Organic Compound Layer

Then, a hole injection layer, a hole transport layer, and an emission layer were formed in this order on the charge injection transport layer 54 by vacuum deposition. In this case, a laminate including the hole injection layer, the hole transport layer, and the emission layer formed in this step functions as the first organic compound layer 55. Note that, in this example, the thickness in total of the first organic compound layer 55 was 250 nm, and, as the emission material included in the emission layer, an emission material for red light emission was used. Further, constituent materials of the layers included in the first organic compound layer 55 (the hole injection layer, the hole transport layer, and the emission layer) were publicly-known organic low molecular materials.

(4) Step of Forming Intermediate layer

Then, an aqueous solution of polyvinyl pyrrolidone was applied at least onto the first organic compound layer 55, and a thin film was formed by spin coating. Then, by drying the thin film, the intermediate layer 61 was formed. In this case, the thickness of the intermediate layer 61 was 400 nm.

(5) Step of Forming First Resist-Resistant Protective Layer

Then, an SiN film was formed on the intermediate layer 61 by plasma CVD to form the first resist-resistant protective layer 62 (FIG. 3C). In this case, the thickness of the first resist-resistant protective layer 62 was 2 μm.

(6) Step of Forming First Resist Layer

Then, a positive type photoresist was applied onto the first resist-resistant protective layer 62. By forming a film by spin coating and carrying out drying, the first resist layer 63 was formed (FIG. 3D).

(7) Developing Step

Then, by carrying out exposure and development in a predetermined pattern using a mask exposure system, the pattern of the first resist layer 63 was formed in a region corresponding to the first pixel 2a (FIG. 3E).

(8) Step of Processing First Organic Compound Layer

Then, the first resist-resistant protective layer 62, the first organic compound layer 55, and the charge injection transport layer 54 provided in the region in which the first resist layer 63 had been removed were removed by a method described in the following (FIG. 3F).

By carrying out dry etching with use of the remaining first resist layer 63 as a mask, the first resist-resistant protective layer 62, the first organic compound layer 55, and the charge injection transport layer 54 were removed in sequence. In this case, an RIE system was used as the dry etching system, and a CF₄ gas was used as the etching gas.

(9) Step of Forming Second Organic Compound Layer

Then, the second organic compound layer 56 was formed over the entire display region on the substrate 40 (FIG. 3G). In this example, the thickness in total of the second organic compound layer 56 was 150 nm, and, as the emission material included in the emission layer, an emission material for blue light emission was used. Further, a constituent material of a layer included in the second organic compound layer 56 was a publicly-known organic low molecular material. Note that, in this example, the second organic compound layer 56 is not necessarily required to be formed over the entire display region on the substrate 40, and it is enough that the second organic compound layer 56 is provided at least on the second pixel electrode 52. When the second organic compound layer 56 is selectively formed in a specific region of the display region on the substrate 40, for example, vapor deposition using a metal mask may be used.

(10) Step of Processing Second Organic Compound Layer (Immersing Step)

Then, by immersing the substrate 40 in water and dissolving a constituent material of the intermediate layer 61, the second organic compound layer 56 provided in the region of the first pixel 2a was lifted off together with the first resist-resistant protective layer 62 and the first resist layer 63 (FIG. 3H). Thus, the second organic compound layer 56 provided in the region of the first pixel 2a was removed.

(11) Step of Forming Intermediate Layer and Second Resist-Resistant Protective Layer

Then, by methods similar to the above-mentioned “(4) Step of Forming Intermediate layer” and “(5) Step of Forming First Resist-resistant Protective Layer”, the intermediate layer 61 and the second resist-resistant protective layer 64 were formed in sequence (FIG. 3I).

(12) Step of Forming Second Resist Layer

Then, a positive type photoresist was applied onto the second resist-resistant protective layer 64. By forming film by spin coating and carrying out drying, the second resist layer 65 was formed (FIG. 3J).

(13) Developing Step

Then, by carrying out exposure and development in a predetermined pattern using a mask exposure system, the pattern of the second resist layer 65 was formed in a region corresponding to the first pixel 2a and the second pixel 2b (FIG. 3K).

(14) Step of Processing Second Organic Compound Layer (Etching Step)

Then, the second resist-resistant protective layer 64 and the second organic compound layer 56 provided in the region in which the second resist layer 65 had been removed were removed by a method described in the following (FIG. 3L).

By carrying out dry etching with use of the remaining second resist layer 65 as a mask, the second resist-resistant protective layer 64 and the second organic compound layer 56 were removed in sequence. In this case, an RIE system was used as the dry etching system, and an O₂ gas was used as the etching gas. When this step was carried out, a part of the charge injection transport layer (55a, 55b, and 55c) remained in portions in the shadow developed by the grain 53a of the electrode material and the foreign matter 41 which might exist on the surface of the third pixel electrode 53 and developed by the electrode level difference 42 developed when the third pixel electrode 53 was formed.

(15) Step of Forming Third Organic Compound Layer

Then, the third organic compound layer 57 was formed over the entire display region on the substrate 40 (FIG. 3M). In this example, the thickness in total of the third organic compound layer 57 was 150 nm, and, as the emission material included in the emission layer, an emission material for green light emission was used. Further, a constituent material of a layer included in the third organic compound layer 57 was a publicly-known organic low molecular material.

(16) Step of Processing Third Organic Compound Layer

Then, by immersing the substrate 40 in water and dissolving a constituent material of the intermediate layer 61, the third organic compound layer 57 provided in the regions of the first pixel 2a and the second pixel 2b was lifted off together with the second resist-resistant protective layer 64 and the second resist layer 65 (FIG. 3N). Thus, the third organic compound layer 57 provided in the regions of the first pixel 2a and the second pixel 2b was removed.

(17) Step of Forming Counter Electrode

Then, the counter electrode 58 which was an electrode common to all of the pixels (2a, 2b, and 2c) was formed on the first organic compound layer 55, the second organic compound layer 56, and the third organic compound layer 57 by a method described in the following (FIG. 3O).

An Ag film was formed by sputtering on the first organic compound layer 55, the second organic compound layer 56, and the third organic compound layer 57 to form the counter electrode 58. In this case, the thickness of the counter electrode 58 was 20 nm.

(18) Encapsulating Step

Finally, an SiN film was formed on the counter electrode 28 by CVD to form an encapsulating film (not shown) for preventing moisture from entering the organic compound layers 55, 56, and 57. In this case, the thickness of the encapsulating film was 2,000 nm.

As described above, the organic EL display device having three kinds of emission colors (red, green, and blue) was obtained. Note that, similarly to the case of Example 1, also in the organic EL display device manufactured in this example, predetermined organic compound layers were arranged on predetermined pixel electrodes with high accuracy. Further, when the manufactured organic EL display device was caused to emit light, no defective light emission was observed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-238344, filed Oct. 31, 2011, which is hereby incorporated by reference herein in its entirety.

What is claimed is:

1. A method of manufacturing an organic electroluminescence display device, comprising:
forming, on a first pixel electrode and a second pixel electrode which are formed on a substrate, a charge injection transport layer which comprises a charge injection transport material using a forming method capable of covering up a portion to be concealed;
forming a first organic compound layer on the charge injection transport layer;
processing the first organic compound layer to remove the first organic compound layer provided at least on the second pixel electrode;
removing at least a part of the charge injection transport layer provided on the second pixel electrode;
forming a second organic compound layer on the second pixel electrode by vacuum deposition;
removing the second organic compound layer on the first pixel electrode; and
forming a counter electrode which is common to a first pixel and a second pixel.

2. The method according to claim 1, wherein the forming method capable of covering up a portion to be concealed comprises an applying method.

3. The method according to claim 1, wherein the forming method capable of covering up a portion to be concealed comprises angle vapor deposition.

4. The method according to claim 1, wherein the forming method capable of covering up a portion to be concealed comprises vapor deposition under low vacuum conditions.

5. The method according to claim 1, wherein the forming a first organic compound layer is carried out by vacuum deposition.

6. The method according to claim 1,
wherein the removing the first organic compound layer comprises:
selectively providing a resist-resistant protective layer on the first organic compound layer above the first pixel electrode; and
removing by dry etching the first organic compound layer provided in a region which is not protected by the resist-resistant protective layer, and
wherein the removing at least a part of the charge injection transport layer comprises removing by dry etching a part of the charge injection transport layer provided in a region in which the first organic compound layer is removed.

7. The method according to claim 1, wherein the removing the second organic compound layer comprises:
selectively providing a resist-resistant protective layer on the second organic compound layer on the second pixel electrode; and
removing by dry etching the second organic compound layer provided in a region which is not protected by the resist-resistant protective layer.

8. A method of manufacturing an organic electroluminescence display device, comprising:
forming, on a first pixel electrode, a second pixel electrode, and a third pixel electrode which are formed on a substrate, a charge injection transport layer which comprises a charge injection transport material using a forming method capable of covering up a portion to be concealed;
forming a first organic compound layer on the charge injection transport layer;
processing the first organic compound layer to remove the first organic compound layer provided at least on the second pixel electrode and on the third pixel electrode;
forming a second organic compound layer by vacuum deposition in a region in which the second pixel electrode is provided;
processing the second organic compound layer to remove the second organic compound layer provided on the first pixel electrode and on the third pixel electrode;
forming a third organic compound layer by vacuum deposition at least on the third pixel electrode;
processing the third organic compound layer to remove the third organic compound layer provided on the first pixel electrode and on the second pixel electrode; and forming a counter electrode which is common to a first pixel, a second pixel, and a third pixel.
